(19) United States
(12) Patent Application Publication
(10) Pub. No.: US 2022/0276055 A1
(43) Pub. Date: Sep. 1, 2022

(54) Aerial Vehicle Launch and Land Site Selection

(71) Applicant: LOON LLC, Mountain View, CA (US)

(72) Inventors: Salvatore J. Candido, Mountain View, CA (US); Bradley Rhodes, Alameda, CA (US); Vincent Carroll, Mountain View, CA (US)

(73) Assignee: LOON LLC, Mountain View, CA (US)

(21) Appl. No.: 17/187,246

(22) Filed: Feb. 26, 2021

(51) Int. Cl. G01C 21/20; G08G 5/00; G05D 1/10; G06F 30/20

(52) U.S. Cl. CPC G01C 21/20; G08G 5/0065; G08G 5/003; G05D 1/101; G06F 30/20; B64B 1/005

(57) ABSTRACT

The technology relates to aerial vehicle launch and land site selection. A method for determining beneficial launch and land sites may include computing a launch delay for a desired time period for each cell in a grid map with a target zone and an existing site located on the grid map, computing a flight time to target for a delay time that accounts for a launch delay, computing a launch time to target based on the launch delay and the flight time to target, receiving geographical restrictions data, and determining an efficiency benefit over the existing site based on the geographical restrictions data and a comparison of the launch time to target of each cell with the launch time to target of the existing site for the desired time period.

### BACKGROUND OF INVENTION

Aerial vehicles are being deployed for many different types of missions and purposes, including providing data connectivity (e.g., broadband and other wireless services), weather observations, Earth observations, cargo transport, and more. Particularly for lighter-than-air (LTA) or partially wind-driven vehicles, the ability to provide appropriate demand for a fleet or sub-fleet to service a mission at given geographical locations can vary depending on locations at which vehicles may launch or land and weather conditions. Typically, the process of planning a launch and landing site is a largely manual process, and at the least, a very computation intensive process.

Thus, it is desirable to have improved aerial vehicle launch and land site selection.

### BRIEF SUMMARY

The present disclosure provides techniques for aerial vehicle launch and land site selection. A method for determining beneficial launch and land sites may include computing a launch delay for a plurality of times within a desired time period for each cell in a grid map, the grid map comprising a target zone and an existing site; computing a flight time to target for a delay time, the delay time comprising a time of the plurality of times plus the time's respective launch delay, the flight time to target indicating an amount of time for an aerial vehicle to travel from a respective cell in the grid map to a target zone on the grid map; computing a launch time to target based on the launch delay and the flight time to target; receiving geographical restrictions data; and determining an efficiency benefit over the existing site based on the geographical restrictions data and a comparison of the launch time to target of each cell with the launch time to target of the existing site for each of the plurality of times. In some examples, the method also may include evaluating a proposed launch site based on the efficiency benefit of the cell in the grid map containing the proposed launch site.

In some examples, computing the flight time to target comprises initializing the grid map at an end time, wherein each cell on the grid map comprising the target zone is labeled with a zero time to target value, and each cell on the grid map outside of the target zone is labeled with a very high time to target value. In some examples, computing the flight time to target further comprises running a plurality of simulations from a plurality of time steps for all cells in the grid map and at each of a plurality of sample altitudes in an altitude range. In some examples, computing the flight time to target further comprises updating each time to target value based on the results of the plurality of simulations indicating from each of the plurality of time steps where a vehicle ends up at the end of each given time step, until the time to target values have been updated through to the beginning of the time period of interest.

In some examples, the launch delay represents a delay due to a ground wind speed in excess of a ground wind speed threshold. In some examples, the launch delay represents a delay due to a cloud coverage in excess of a cloud coverage threshold. In some examples, the launch delay represents a delay due to a chance of precipitation in excess of a precipitation threshold. In some examples, the launch delay represents a delay due to a maximum number of launches per time period restriction. In some examples, the launch delay represents a delay due to a time of day restrictions for vehicle launches. In some examples, the launch delay represents a delay due to a day of the week restriction for vehicle launches. In some examples, the geographical restrictions data indicates a proximity to a population density in excess of an applicable population density limitation. In some examples, the geographical restrictions data indicates a proximity to a restricted airspace.

In some examples, the method also includes representing on a heat map the efficiency benefit of each cell on the grid map for one of the plurality of times. In some examples, the method also includes representing on a heat map the aggregated efficiency benefit of each cell on the grid map for two or more of the plurality of times.

In some examples, the desired time period comprises a season. In some examples, the desired time period comprises a given week of the year.

A distributed computing system may include a distributed database configured to store flight simulation data and geographical restrictions data; and one or more processors configured to: compute a launch delay for a plurality of times within a desired time period for each cell in a grid map, the grid map comprising a target zone and an existing site, compute a flight time to target for a delay time, the delay time comprising a time of the plurality of times plus the time's respective launch delay, the flight time to target indicating an amount of time for an aerial vehicle to travel from a respective cell in the grid map to a target zone on the grid map, compute a launch time to target based on the launch delay and the flight time to target, receive geographical restrictions data, and determine an efficiency benefit over the existing site based on the geographical restrictions data and a comparison of the launch time to target of each cell with the launch time to target of the existing site for each of the plurality of times.

### BRIEF DESCRIPTION OF THE DRAWINGS

FIGS. 1A-1B are diagrams of exemplary operational systems for which aerial vehicle launch and land site selection may be implemented, in accordance with one or more embodiments;

FIG. 2A is a simplified block diagram of an exemplary computing system forming part of the systems of FIGS. 1A-2, in accordance with one or more embodiments;

FIG. 2B is a simplified block diagram of an exemplary distributed computing system for implementing aerial vehicle launch and land site selection, in accordance with one or more embodiments;

FIGS. 3A-3B are flow diagrams illustrating exemplary methods for aerial vehicle launch and land site selection, in accordance with one or more embodiments; and

FIGS. 4A-4C are exemplary efficiency benefit maps resulting from aerial vehicle launch and land site selection, in accordance with one or more embodiments.

The figures depict various example embodiments of the present disclosure for purposes of illustration only. One of ordinary skill in the art will readily recognize from the following discussion that other example embodiments based on alternative structures and methods may be implemented without departing from the principles of this disclosure, and which are encompassed within the scope of this disclosure.

### DETAILED DESCRIPTION

The Figures and the following description describe certain embodiments by way of illustration only. One of ordinary skill in the art will readily recognize from the following description that alternative embodiments of the structures and methods illustrated herein may be employed without departing from the principles described herein. Reference will now be made in detail to several embodiments, examples of which are illustrated in the accompanying figures.

The above and other needs are met by the disclosed methods, a non-transitory computer-readable storage medium storing executable code, and systems for managing nighttime power for solar-powered vehicles. The terms “aerial vehicle” and “aircraft” are used interchangeably herein to refer to any type of vehicle capable of aerial movement, including, without limitation, High Altitude Platforms (HAPs), High Altitude Long Endurance (HALE) aircraft, unmanned aerial vehicles (UAVs), passive lighter than air vehicles (e.g., floating stratospheric balloons, other floating or wind-driving vehicles), powered lighter than air vehicles (e.g., balloons and airships with some propulsion capabilities), fixed-wing vehicles (e.g., drones, rigid kites, gliders), various types of satellites, and other high altitude aerial vehicles.

The invention is directed to aerial vehicle launch and land site selection based on analysis of wind data (e.g., running simulations of aerial vehicle flights) for a plurality of cells (e.g., S2 cells, latitude-longitude pairs) on a grid map, the wind data from a predetermined time period (e.g., 1 year, 6 years, a decade, a preceding number of years, or more or less). This hindcast technique allows you to determine the areas on the grid map for which a launch and land site for aerial vehicles would increase efficiency (e.g., reduce transit time from an aerial vehicle launch to a target zone, availability of a potential launch site for launching aerial vehicles based on meteorological, regulatory conditions, geopolitical and physical constraints) over existing launch and land sites. The predetermined time period is preferably long enough to provide sufficient wind data in a desired time period (e.g., a year, a given month each year, a given season, a given range of days or weeks of each year, a number of years in a climate cycle) to run a plurality of simulations.

A method for generating a launch site forecast may include: computing a launch_delay for a plurality of launch times within a desired time period for each cell in a grid map, the grid map comprising a target zone (e.g., a service region, point of interest, test area, or any other desired location for a vehicle to travel) and an existing site; computing a flight_time_to_target for a delay time, the delay time comprising a launch time of the plurality of launch times plus the launch time's respective launch_delay; computing a launch_time_to_target based on the launch_delay and the flight_time_to_target; receiving geographical restrictions data, which may comprise regulatory time windows, no-fly zones, other airspace restrictions (e.g., countries or regions with no or limited permissions), combinations thereof; and determining an efficiency benefit over the existing site by comparing the launch_time_to_target of each cell with the launch_time_to_target of the existing site for each of the plurality of launch times, in consideration of the geographical restrictions data. In some examples, the grid map also may include an identified proposed new launch site, and the method may evaluate how beneficial the proposed new launch site may be. In other examples, all locations on the grid map that do not comprise a target zone or an existing site may be evaluated and considered as a proposed new launch site.

Launch_delay represents an amount of time a launch time (t_{launch}) will be delayed until weather at a potential launch site is suitable for a launch. Launch suitability may be based on a number of predetermined criteria, which may include weather related criteria (e.g., a ground wind speed threshold, a cloud coverage threshold, a precipitation threshold), regulation related criteria, or other limiting factors (e.g., time of day restrictions, day of the week restrictions). Thus, an equation for launch_time_to_target may be represented as:

launch_time_to_target=(launch_delay at t_{launch})+(flight_time_to_target at t_{launch+delay})

wherein t_{launch+delay} is a time at t_{launch}+launch_delay.

A method for determining a flight_time_to_target for each cell in the grid map may include: initializing the grid map such that at a time t_{end} representing an end of a time period of interest, each cell on the grid map (e.g., of a region or the globe) in a target zone (cell_{targ}) being labeled 0 (i.e., hours, days, minutes, or other time unit) time to target value, and each cell outside of the target zone being labeled a high (e.g., infinity, 100 days, or other similar number that may be higher than a possible time period of interest) time to target value; running a plurality of simulations from a time step back (i.e., t_{end}−x, where x=a time step represented in a time unit) at all cells in the grid map and at each sample altitude (i.e., pressure level) in an altitude range (e.g., each meter, each kilometer, each pascal, each kilopascal, etc.) to determine where a vehicle would end up in the time step; updating a time to target value for each cell on the map where a vehicle from that cell ended up in the target zone during the time step by adding x or other value less than x representing the time to reach a cell_{targ}; repeating the last two steps until you reach a beginning of the time period of interest; and generating a map of time to target values.

Using the map of time to target values, a comparison may be made between an existing site and a proposed new site to determine an efficiency benefit for each cell. The efficiency benefit also may account for a demand for vehicles to service a target zone, for example, during a given time period (e.g., days, weeks, periods, seasons). For example, if there is demand for ten (10) vehicles to service a target zone, time to target from the cell comprising the target zone is 0 days per launch, average time to target from an existing site is 30 days per launch, and average time to target from a proposed new site is 15 days per launch, then an efficiency benefit for the proposed new site over the existing site would be 15 days per vehicle launch.

The map of time to target values also may be used to determine a cost of supplying sufficient vehicles to a service location to meet demand with different sets of launch sites. For example, if demand is for X vehicles to arrive at the service location each week, the above method may be used to determine how much cost waste will be incurred from transit times (i.e., expected launch_time_to_target values). A map of time to target values with added launch sites may be used to determine the feasibility of using N sites to supply X vehicles to the service location each week, and the reduction of vehicle cost from the perspective of transit time savings (i.e., as compared to an existing set of sites, or other different set of sites). For example, launch_time_to_target values also can be used to determine a time cost for ensuring an adequate supply of vehicles to a target zone (i.e., a destination) by determining a sum of launch_time_to_target values for a desired number of vehicles to be launched (e.g., in succession or in parallel, depending on the capabilities of a launch site) from a site (or two or more sites, for example, if a single site is unable to launch the desired number of vehicles in the desired time window) in order to provide the adequate supply of vehicles to the target zone in a timely fashion. The sum of launch_time_to_target values, or total vehicle transit cost for providing the adequate supply of vehicles, can be used to inform the feasibility and desirability of existing and new launch sites.

In some examples, the efficiency benefit of each cell may be represented on a heat map comprising the cells on the grid map and indicating for each cell a level of efficiency benefit (e.g., using a color gradient, values, or other graded indication) over the existing site. Efficiency benefit maps may be generated for different existing sites, different desired time periods, and different geographical regions to aid in the selection of future launch and land sites. A similar method as described herein may be used to forecast sites where there may be efficiency benefit gains for both launch and land, taking into consideration landing criteria.

Example Systems

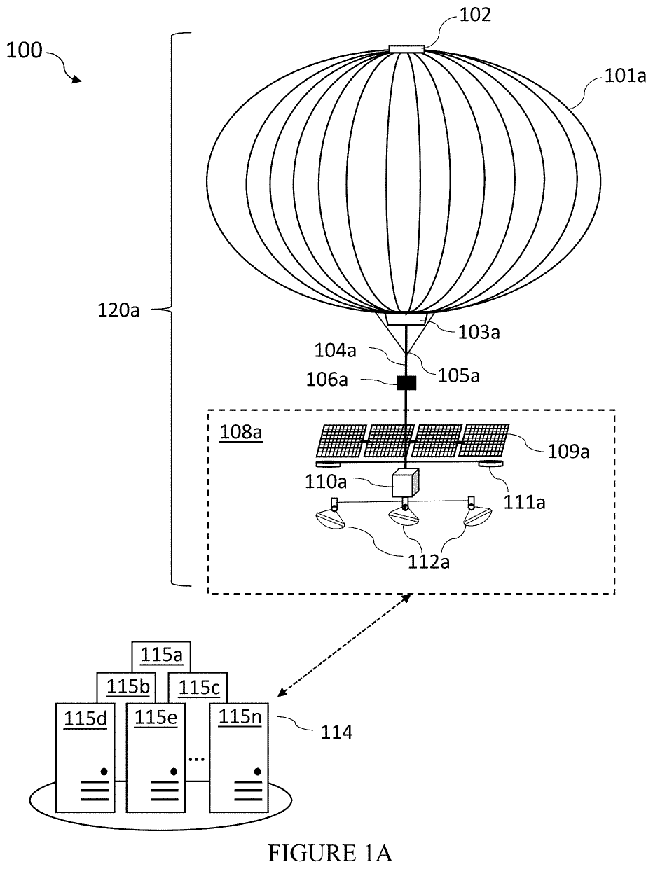

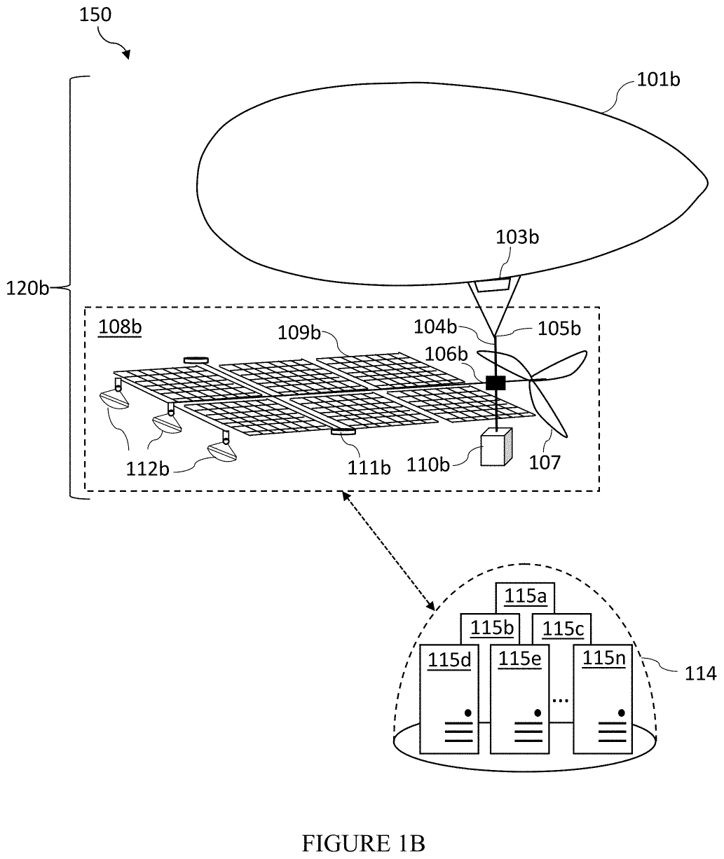

FIGS. 1A-1B are diagrams of exemplary operational systems for which aerial vehicle launch and land site selection may be implemented, in accordance with one or more embodiments. In FIG. 1A, there is shown a diagram of system 100 for control and operation of aerial vehicle 120a. In some examples, aerial vehicle 120a may be a passive vehicle, such as a balloon or satellite, wherein most of its directional movement is a result of environmental forces, such as wind and gravity. In other examples, aerial vehicles 120a may be actively propelled. In an embodiment, system 100 may include aerial vehicle 120a and ground station 114. In this embodiment, aerial vehicle 120a may include balloon 101a, plate 102, altitude control system (ACS) 103a, connection 104a, joint 105a, actuation module 106a, and payload 108a. In some examples, plate 102 may provide structural and electrical connections and infrastructure. Plate 102 may be positioned at the apex of balloon 101a and may serve to couple together various parts of balloon 101a. In other examples, plate 102 also may include a flight termination unit, such as one or more blades and an actuator to selectively cut a portion and/or a layer of balloon 101a. In other examples, plate 102 further may include other electronic components (e.g., a sensor, a part of a sensor, power source, communications unit). ACS 103a may include structural and electrical connections and infrastructure, including components (e.g., fans, valves, actuators, etc.) used to, for example, add and remove air from balloon 101a (i.e., in some examples, balloon 101a may include an interior ballonet within its outer, more rigid shell that may be inflated and deflated), causing balloon 101a to ascend or descend, for example, to catch stratospheric winds to move in a desired direction. Balloon 101a may comprise a balloon envelope comprised of lightweight and/or flexible latex or rubber materials (e.g., polyethylene, polyethylene terephthalate, chloroprene), tendons (e.g., attached at one end to plate 102 and at another end to ACS 103a) to provide strength and stability to the balloon structure, and a ballonet, along with other structural components. In various embodiments, balloon 101a may be non-rigid, semi-rigid, or rigid.

Connection 104a may structurally, electrically, and communicatively, connect balloon 101a and/or ACS 103a to various components comprising payload 108a. In some examples, connection 104a may provide two-way communication and electrical connections, and even two-way power connections. Connection 104a may include a joint 105a, configured to allow the portion above joint 105a to pivot about one or more axes (e.g., allowing either balloon 101a or payload 108a to tilt and turn). Actuation module 106a may provide a means to actively turn payload 108a for various purposes, such as improved aerodynamics, facing or tilting solar panel(s) 109a advantageously, directing payload 108a and propulsion units (e.g., propellers 107 in FIG. 1B) for propelled flight, or directing components of payload 108a advantageously.

Payload 108a may include solar panel(s) 109a, avionics chassis 110a, broadband communications unit(s) 111a, and terminal(s) 112a. Solar panel(s) 109a may be configured to capture solar energy to be provided to a battery or other energy storage unit, for example, housed within avionics chassis 110a. Avionics chassis 110a also may house a flight computer (e.g., computing device 301, as described herein), a transponder, along with other control and communications infrastructure (e.g., a controller comprising another computing device and/or logic circuit configured to control aerial vehicle 120a). Communications unit(s) 111a may include hardware to provide wireless network access (e.g., LTE, fixed wireless broadband via 5G, Internet of Things (IoT) network, free space optical network or other broadband networks). Terminal(s) 112a may comprise one or more parabolic reflectors (e.g., dishes) coupled to an antenna and a gimbal or pivot mechanism (e.g., including an actuator comprising a motor). Terminal(s) 112(a) may be configured to receive or transmit radio waves to beam data long distances (e.g., using the millimeter wave spectrum or higher frequency radio signals). In some examples, terminal(s) 112a may have very high bandwidth capabilities. Terminal(s) 112a also may be configured to have a large range of pivot motion for precise pointing performance. Terminal(s) 112a also may be made of lightweight materials.

In other examples, payload 108a may include fewer or more components, including propellers 107 as shown in FIG. 1B, which may be configured to propel aerial vehicles 120a-b in a given direction. In still other examples, payload 108a may include still other components well known in the art to be beneficial to flight capabilities of an aerial vehicle. For example, payload 108a also may include energy capturing units apart from solar panel(s) 109a (e.g., rotors or other blades (not shown) configured to be spun, or otherwise actuated, by wind to generate energy). In another example, payload 108a may further include or be coupled to an imaging device, such as a downward-facing camera and/or a star tracker. In yet another example, payload 108a also may include various sensors (not shown), for example, housed within avionics chassis 110a or otherwise coupled to connection 104a or balloon 101a. Such sensors may include Global Positioning System (GPS) sensors, wind speed and direction sensors such as wind vanes and anemometers, temperature sensors such as thermometers and resistance temperature detectors (i.e., RTDs), speed of sound sensors, acoustic sensors, pressure sensors such as barometers and differential pressure sensors, accelerometers, gyroscopes, combination sensor devices such as inertial measurement units (IMUs), light detectors, light detection and ranging (LIDAR) units, radar units, cameras, other image sensors, and more. These examples of sensors are not intended to be limiting, and those skilled in the art will appreciate that other sensors or combinations of sensors in addition to these described may be included without departing from the scope of the present disclosure.

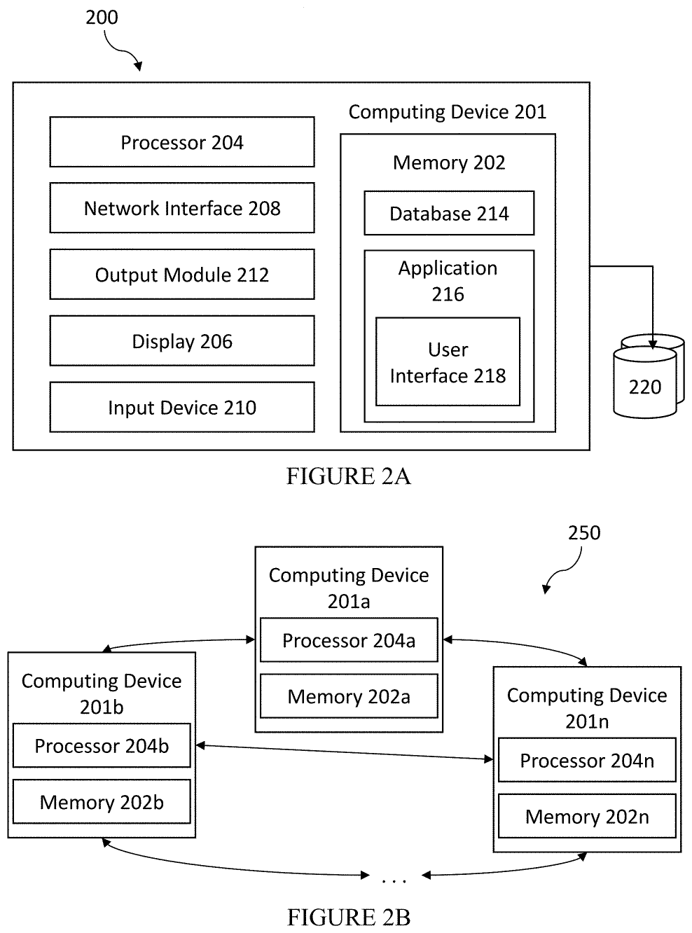

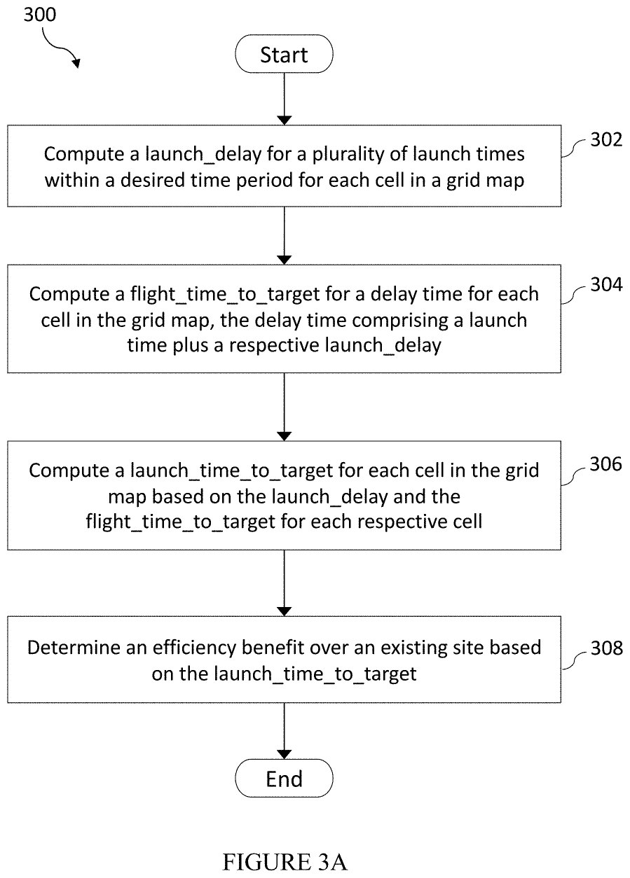

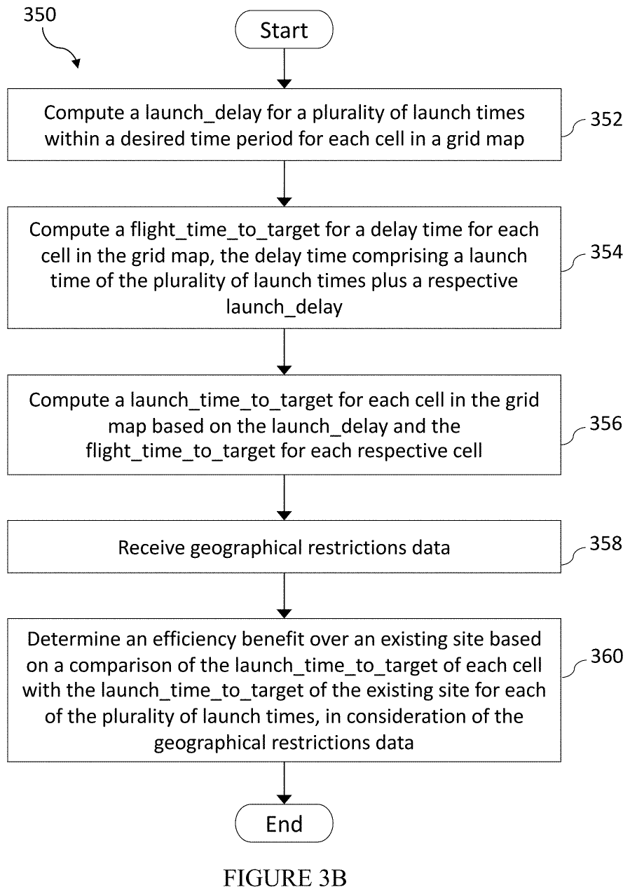

Ground station 114 may include one or more server computing devices 115a-n, which in turn may comprise one or more computing devices (e.g., computing device 301 in FIG. 3). In some examples, ground station 114 also may include one or more storage systems, either housed within server computing devices 115a-n, or separately (see, e.g., computing device 301 and repositories 320). Ground station 114 may be a datacenter servicing various nodes of one or more networks (e.g., aerial vehicle network 200 in FIG. 2).

FIG. 1B shows a diagram of system 150 for control and operation of aerial vehicle 120b. All like-numbered elements in FIG. 1B are the same or similar to their corresponding elements in FIG. 1A, as described above (e.g., balloon 101a and balloon 101b may serve the same function, and may operate the same as, or similar to, each other). In some examples, balloon 101b may comprise an airship hull or dirigible balloon. In this embodiment, aerial vehicle 120b further includes, as part of payload 108b, propellers 107, which may be configured to actively propel aerial vehicle 120b in a desired direction, either with or against a wind force to speed up, slow down, or re-direct, aerial vehicle 120b. In this embodiment, balloon 101b also may be shaped differently from balloon 101a, to provide different aerodynamic properties. In some examples, balloon 101b may include one or more fins (not shown) coupled to one or more of a rear, upper, lower, or side, surface (i.e., relative to a direction in which balloon 101b is heading).

As shown in FIGS. 1A-1B, aerial vehicles 120a-b may be largely wind-influenced aerial vehicles, for example, balloons carrying a payload (with or without propulsion capabilities) as shown, or fixed wing high altitude drones (e.g., aerial vehicle 211c in FIG. 2) with gliding and/or full propulsion capabilities. However, those skilled in the art will recognize that the systems and methods disclosed herein may similarly apply and be usable by various other types of aerial vehicles.

FIG. 2A is a simplified block diagram of an exemplary computing system forming part of the systems of FIGS. 1A-2, in accordance with one or more embodiments. In one embodiment, computing system 200 may include computing device 201 and storage system 220. Storage system 220 may comprise a plurality of repositories and/or other forms of data storage, and it also may be in communication with computing device 201. In another embodiment, storage system 220, which may comprise a plurality of repositories, may be housed in one or more of computing device 201 (not shown). In some examples, storage system 220 may store state data, commands (e.g., flight, navigation, communications, mission, fallback), flight simulation data, geographical restrictions data, and other various types of information as described herein. This information may be retrieved or otherwise accessed by one or more computing devices, such as computing device 201 or server computing devices 115a-n in FIGS. 1A-1B, in order to perform some or all of the features described herein. Storage system 220 may comprise any type of computer storage, such as a hard-drive, memory card, ROM, RAM, DVD, CD-ROM, write-capable, and read-only memories. In addition, storage system 220 may include a distributed storage system where data is stored on a plurality of different storage devices, which may be physically located at the same or different geographic locations (e.g., in a distributed computing system such as system 250 in FIG. 2B). Storage system 220 may be networked to computing device 201 directly using wired connections and/or wireless connections. Such network may include various configurations and protocols, including short range communication protocols such as Bluetooth™, Bluetooth™ LE, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

Computing device 201 also may include a memory 202. Memory 202 may comprise a storage system configured to store a database 214 and an application 216. Application 216 may include instructions which, when executed by a processor 204, cause computing device 201 to perform various steps and/or functions, as described herein. Application 216 further includes instructions for generating a user interface 218 (e.g., graphical user interface (GUI)). Database 214 may store various algorithms and/or data, including neural networks (e.g., encoding flight policies, as described herein) and data regarding wind patterns, weather forecasts, past and present locations of aerial vehicles (e.g., aerial vehicles 120a-b), sensor data, simulation data, geographical characteristics and restrictions data, map information, air traffic information, among other types of data. Memory 202 may include any non-transitory computer-readable storage medium for storing data and/or software that is executable by processor 204, and/or any other medium which may be used to store information that may be accessed by processor 204 to control the operation of computing device 201.

Computing device 201 may further include a display 206, a network interface 208, an input device 210, and/or an output module 212. Display 206 may be any display device by means of which computing device 201 may output and/or display data. Network interface 208 may be configured to connect to a network using any of the wired and wireless short range communication protocols described above, as well as a cellular data network, a satellite network, free space optical network and/or the Internet. Input device 210 may be a mouse, keyboard, touch screen, voice interface, and/or any or other hand-held controller or device or interface by means of which a user may interact with computing device 201. Output module 212 may be a bus, port, and/or other interface by means of which computing device 201 may connect to and/or output data to other devices and/or peripherals.

In some examples computing device 201 may be located remote from an aerial vehicle (e.g., aerial vehicles 120a-b) and may communicate with and/or control the operations of an aerial vehicle, or its control infrastructure as may be housed in avionics chassis 110a-b, via a network. In one embodiment, computing device 201 is a data center or other control facility (e.g., configured to run a distributed computing system as described herein), and may communicate with a controller and/or flight computer housed in avionics chassis 110a-b via a network. As described herein, system 200, and particularly computing device 201, may be used for planning a flight path or course for an aerial vehicle based on wind and weather forecasts to move said aerial vehicle along a desired heading or within a desired radius of a target location. Various configurations of system 200 are envisioned, and various steps and/or functions of the processes described below may be shared among the various devices of system 200, or may be assigned to specific devices.

FIG. 2B is a simplified block diagram of an exemplary distributed computing system for implementing aerial vehicle launch and land site selection, in accordance with one or more embodiments. System 250 may comprise two or more computing devices 201a-n. In some examples, each of 201a-n may comprise one or more of processors 204a-n, respectively, and one or more of memory 202a-n, respectively. Processors 204a-n may function similarly to processor 204 in FIG. 2, as described above. Memory 202a-n may function similarly to memory 202 in FIG. 2, as described above.

Example Methods

FIGS. 3A-3B are flow diagrams illustrating exemplary methods for aerial vehicle launch and land site selection, in accordance with one or more embodiments. Method 300 begins with computing a launch_delay for a plurality of launch times within a desired time period for each cell in a grid map. The grid map may include an existing site and a plurality of target zones, including without limitation, a service region, a point of interest, a test area, and other desired location for an aerial vehicle to travel. The grid map also may include one or more potential new launch sites. A launch_delay may represent an amount of time a launch time will be delayed until a potential launch site is suitable for a launch. Launch suitability may be based on a number of predetermined criteria, including weather criteria, regulation criteria, or other limiting factors. For example, there may be a ground wind speed threshold (e.g., 10 miles per hour (mph), 15 mph, 20 mph, or more or less or between depending on type of vehicle and launch site characteristics), a cloud coverage threshold (e.g., less than 40%, 45%, 50%, 55%, or more or less or between depending on type of vehicle and launch site characteristics) and/or a precipitation threshold (e.g., no rain, no snow, a given percentage chance of precipitation, or other precipitation-related limitation), above which a launch would not be suitable (i.e., inadvisable or not allowed). In another example, regulations may restrict a number of launches per time period (e.g., maximum number of launches per hour(s), day(s), week(s), month(s), etc.), a location may have time of day or day of the week restrictions for launches (e.g., based on geographical, climate, population proximity, population density, and other considerations), and other factors that may limit times in which a launch site is suitable for a launch, and thus contribute to a launch_delay. For example, launch_delay for a morning (or more specific time) of a day for which the weather is suitable and all other launch criteria are met, may be zero, whereas launch_delay for that same evening where the next morning is expected to have the same weather suitability, but there are no nighttime launches allowed at the given site, may be a time until next sunrise (e.g., 8 hours, 9 hours, 10 hours, or more, between or less depending on a time of year and geographical location (e.g., a latitude and longitude).

A flight_time_to_target for a delay time for each cell in the grid map may be computed at step 304, the delay time comprising a launch time plus a respective launch_delay. The flight_time_to_target may represent an amount of time it takes to travel from a starting (i.e., launch) location to an ending (i.e., destination) location after launch. In some examples, the flight_time_to_target may be generated by a map builder configured to generate flight maps indicating flight routes and predicted travel times to a target destination (e.g., as described in U.S. patent application Ser. No. 16/222,309, filed Dec. 17, 2018, titled “Wind Data Based Flight Maps for Aircraft,” and U.S. patent application Ser. No. 16/222,614, filed Dec. 17, 2018, titled “Wind Data Based Flight Maps for Aircraft”). For example, determining a flight_time_to_target may include initializing a grid map such that at an end time (i.e., an end of a time period of interest), wherein each cell on the grid map in a target zone (i.e., one or more cells comprising a destination location) is labeled with a zero time to target value, and each cell outside of the target zone is labeled with a very high time to target value (e.g., infinity, hundreds of days, or other number exceeding the time period of interest), then running a plurality of simulations from a plurality of time steps backwards for all cells in the grid map and at each of a plurality of sample altitudes in an altitude range, updating each time to target value based on the results of the plurality of simulations indicating from each of the plurality of time steps backwards where a vehicle ends up at the end of each given time step, and repeating the last two steps until the time to target values have been updated through the beginning of the time period of interest. In other examples, the flight_time_to_target may be computed differently (e.g., estimation or extrapolation using historical wind, weather, and flight data, various simulation methods).

A launch_time_to_target for each cell in the grid map may be computed based on the launch_delay and the flight_time_to_target for each respective cell at step 306. An efficiency benefit over an existing site may be determined based on the launch_time_to_target at step 308. In some examples, efficiency benefit over existing launch and land sites may represent a reduction in transit time from an aerial vehicle launch to the aerial vehicle arrival at a target zone, and availability of a potential launch site for launching aerial vehicles based on meteorological and regulatory conditions. Meteorological conditions that may favor or disfavor launch site availability may include a size (i.e., cumulative or average) of weather windows that allow for launch based on factors including, without limitation, precipitation amounts, cloud coverage and characteristics, and turbulence. Regulatory conditions that may favor or disfavor launch site availability may include a size (i.e., cumulative or average) of regulatory windows that allow for launch based on factors including, without limitation, air traffic flows and restrictions, regulations allowing or disallowing launches and landings during stated or periodic time windows (e.g., between or during given hours of a day, daytime, nighttime).

For example, wherein a launch_time_to_target for a first cell comprising an existing launch site may be thirty (30) days (i.e., averaged) on a given launch date within a time frame, and a launch_time_to_target for a second cell comprising a proposed launch site may be fifteen (15) days on the given launch date during the same time frame, the efficiency benefit may be 15 days per vehicle launch on the given launch date during the time frame. This efficiency benefit also may be stated or represented as 15 days multiplied by a number of desired vehicle launches (e.g., a number of vehicles needed for service at a target zone or desired destination). In some examples, an arrival time at a target zone or desired destination may be used to determine the time frame and launch dates to compare at each launch site (e.g., given a desired arrival time, a first launch date and time frame at the first cell may be determined on which a launch would deliver the number of desired vehicles to the target zone in a timely manner, and a second launch date and time frame at the second cell may be determined on which a launch would deliver the number of desired vehicles to the target zone in a timely manner).

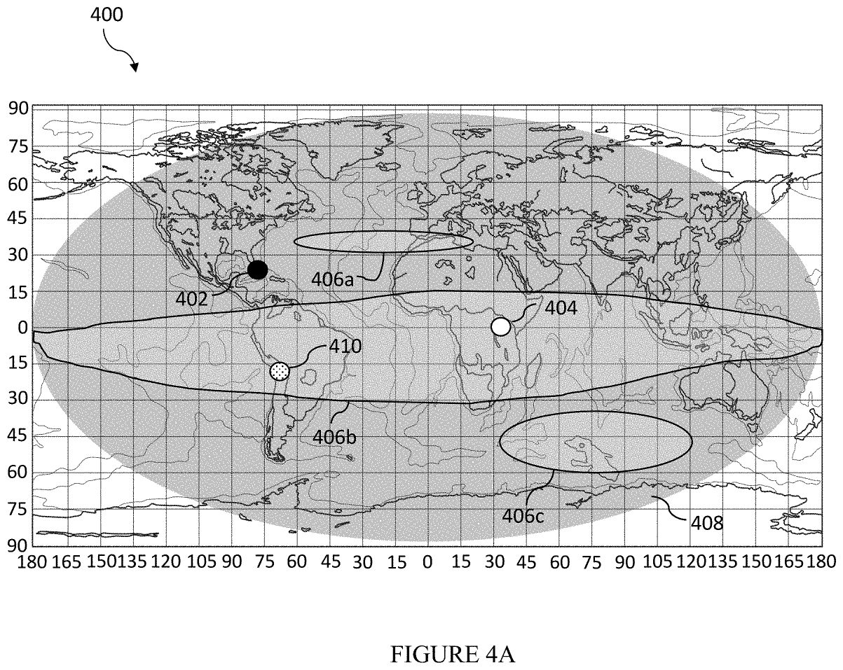

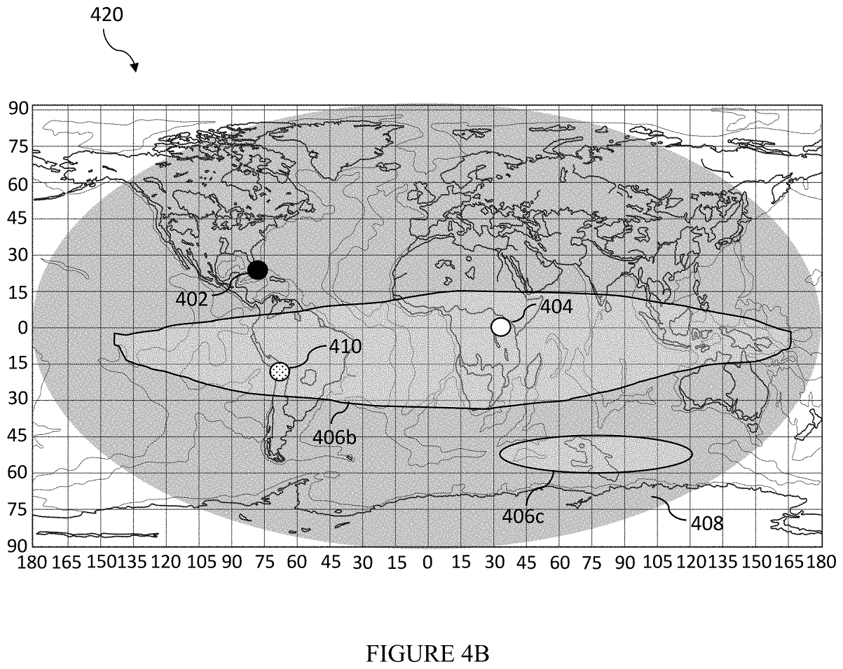

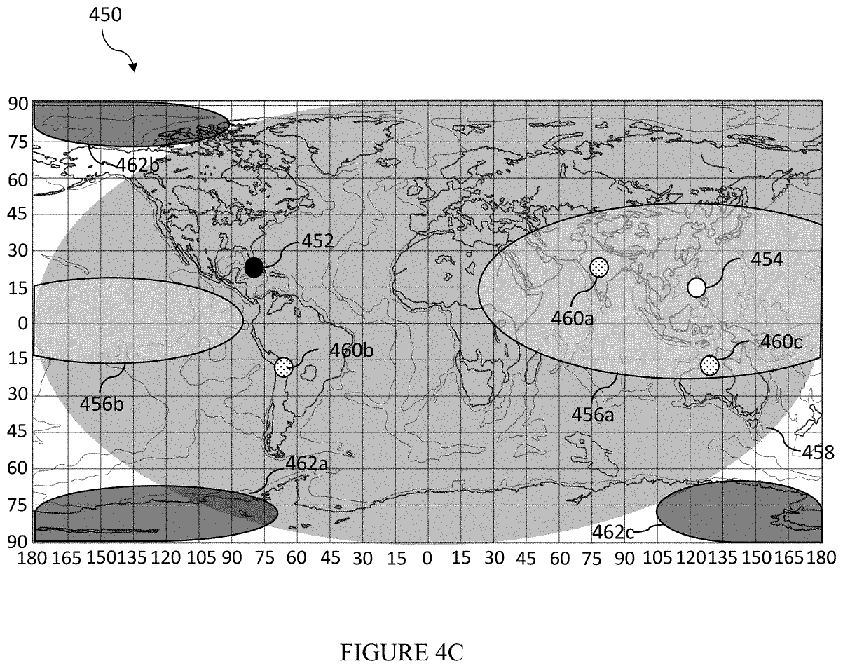

In some examples, efficiency benefit also may represent launch site concerns due to geographical restrictions due to, for example, geopolitical, contractual and physical constraints. Geopolitical and physical constraints may include, without limitation, stability of a political regime, cost associated with importing and exporting materials (e.g., tariffs, accessibility (e.g., availability and cost of accessing of ports and points of entry and exit), resources (e.g., availability and cost of manpower and transport vehicles), and the like), other costs of doing business. Other constraints may include, for example, ascent and descent path restrictions based on a physical manner by which a type of vehicle ascends and descends, as well as any restrictions on types of flights allowed to ascend and descend within a cell in a grid map (e.g., a proposed launch and/or landing zone) and its proximity (e.g., whether an ascent or descent path may cause a vehicle to exceed applicable population density limitations or restricted airspace limitations). Contractual constraints may specify geographical boundaries within which launches may occur and vehicles may travel. These geographical restrictions may be considered in method 350 in FIG. 3B. Method 350 may begin with computing a launch_delay for a plurality of launch times within a desired time period for each cell in a grid map at step 352. A flight_time_to_target for a delay time for each cell in the grid map may be computed at step 354, the delay time comprising a launch time of the plurality of launch times plus a respective launch_delay. A launch_time_to_target for each cell in the grid map may be computed, at step 356, based on the launch_delay and the flight_time_to_target for each respective cell. Geographical restrictions data may be received at step 358. An efficiency benefit over an existing site may be determined based on a comparison of the launch_time_to_target of each cell with the launch_time_to_target of the existing site for each of the plurality of launch times, in consideration of the geographical restrictions data, at step 360. In some examples, the efficiency benefit for each cell may be represented on an efficiency benefit map (e.g., maps 400, 420 and 450 in FIGS. 4A-4C, respectively).

FIGS. 4A-4C are exemplary efficiency benefit maps resulting from aerial vehicle launch and land site selection, in accordance with one or more embodiments. In FIG. 4A, map 400 is a heat map showing example zones with varying efficiency benefits. Heat map 400 includes an existing launch site 402, a target zone 404 (e.g., a destination or service area), and proposed launch site 410. The light grey zones 406a-c may indicate areas of higher efficiency benefit (e.g., higher than efficiency of existing launch site 402) for traveling to target zone 404 for a given time period (e.g., map 400 may represent aggregated efficiency benefit results for a given day, a given week, a given seasons, or other time period, within a calendar year or other type of calendar. The darker grey zone 408 may indicate areas of lower efficiency benefit (e.g., same or similar to efficiency of existing launch site 402). The non-shaded zones outside of zone 408 may indicate the lowest efficiency benefit relative to existing launch site 402. In this example, proposed launch site 410 will provide improved efficiency over existing launch site 402 for launching aerial vehicles to serve target zone 404 during this time period. In other examples, for example for other seasons, weather patterns, dates, etc., given other types of restrictions as described herein, heat map 400 may comprise a greater variety of zones, for example, represented by different colors or a spectrum of colors indicating a spectrum of efficiency, for example, with a zone within a day or less of target zone 404 and a zone for each additional day or week out from target zone 404.

In FIG. 4B, map 420 is another heat map showing the same example zones with varying efficiency benefits, but for a different time period (e.g., another season, week, or day, of the year). Like-numbered elements in FIG. 4B may be the same or similar to those elements in FIG. 4C. For example, existing launch site 402, target zone 404 and proposed launch site 410 may be in the same locations, respectively, as in heat map 400 in FIG. 4A. However, given the different weather and wind patterns and/or other restrictions that may vary with the time period, zones 406b-c and 408 may cover different geographical areas. In this example, proposed launch site 410 is still expected to provide improved efficiency over existing launch site 402 for launching aerial vehicles to serve target zone 404 during this different time period.

In FIG. 4C, heat map 450 shows another set of example zones with varying efficiency benefits given existing launch site 452, target zone 454, and proposed launch sites 460a-c. Light grey zones 456a-b indicate areas of high efficiency benefit over existing launch site 452. Darker grey zone 458 indicate areas of the same or similar efficiency as existing launch site 452, and the darkest grey zones 462a-c indicate areas of lower efficiency than existing launch site 452. In this example, proposed launch sites 460a and 460c are expected to provide improved efficiency over existing launch site 452 for launching aerial vehicles to serve target zone 454 during the represented time period, but proposed launch site 460b is expected to have the same or similar efficiency than existing launch site 452. As described herein, such efficiency benefits may represent hours, days, weeks or months of transit savings, either per vehicle or in aggregate across a desired number of aerial vehicles or an entire fleet. In other examples, two or more target zones may be considered in computing a launch_time_to_target and represented in a heat map.

While specific examples have been provided above, it is understood that the present invention can be applied with a wide variety of inputs, thresholds, ranges, and other factors, depending on the application. For example, the time frames and ranges provided above are illustrative, but one of ordinary skill in the art would understand that these time frames and ranges may be varied or even be dynamic and variable, depending on the implementation.

As those skilled in the art will understand, a number of variations may be made in the disclosed embodiments, all without departing from the scope of the invention, which is defined solely by the appended claims. It should be noted that although the features and elements are described in particular combinations, each feature or element can be used alone without other features and elements or in various combinations with or without other features and elements. The methods or flow charts provided may be implemented in a computer program, software, or firmware tangibly embodied in a computer-readable storage medium for execution by a general-purpose computer or processor.

Examples of computer-readable storage mediums include a read only memory (ROM), random-access memory (RAM), a register, cache memory, semiconductor memory devices, magnetic media such as internal hard disks and removable disks, magneto-optical media, and optical media such as CD-ROM disks.

Suitable processors include, by way of example, a general-purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, or any combination of thereof.

What is claimed is:

1. A method for determining beneficial launch and land sites, the method comprising:
computing a launch delay for a plurality of times within a desired time period for each cell in a grid map, the grid map comprising a target zone and an existing site;
computing a flight time to target for a delay time, the delay time comprising a time of the plurality of times plus the time's respective launch delay, the flight time to target indicating an amount of time for an aerial vehicle to travel from a respective cell in the grid map to a target zone on the grid map;
computing a launch time to target based on the launch delay and the flight time to target;
receiving geographical restrictions data; and
determining an efficiency benefit over the existing site based on the geographical restrictions data and a comparison of the launch time to target of each cell with the launch time to target of the existing site for each of the plurality of times.

2. The method of claim 1, further comprising evaluating a proposed launch site based on the efficiency benefit of the cell in the grid map containing the proposed launch site.

3. The method of claim 1, wherein computing the flight time to target comprises initializing the grid map at an end time, wherein each cell on the grid map comprising the target zone is labeled with a zero time to target value, and each cell on the grid map outside of the target zone is labeled with a very high time to target value.

4. The method of claim 3, wherein computing the flight time to target further comprises running a plurality of simulations from a plurality of time steps for all cells in the grid map and at each of a plurality of sample altitudes in an altitude range.

5. The method of claim 3, wherein computing the flight time to target further comprises updating each time to target value based on the results of the plurality of simulations indicating from each of the plurality of time steps where a vehicle ends up at the end of each given time step, until the time to target values have been updated through to the beginning of the time period of interest.

6. The method of claim 1, wherein the launch delay represents a delay due to a ground wind speed in excess of a ground wind speed threshold.

7. The method of claim 1, wherein the launch delay represents a delay due to a cloud coverage in excess of a cloud coverage threshold.

8. The method of claim 1, wherein the launch delay represents a delay due to a chance of precipitation in excess of a precipitation threshold.

9. The method of claim 1, wherein the launch delay represents a delay due to a maximum number of launches per time period restriction.

10. The method of claim 1, wherein the launch delay represents a delay due to a time of day restrictions for vehicle launches.

11. The method of claim 1, wherein the launch delay represents a delay due to a day of the week restriction for vehicle launches.

12. The method of claim 1, wherein the geographical restrictions data indicates a proximity to a population density in excess of an applicable population density limitation.

13. The method of claim 1, wherein the geographical restrictions data indicates a proximity to a restricted airspace.

14. The method of claim 1, further comprising representing on a heat map the efficiency benefit of each cell on the grid map for one of the plurality of times.

15. The method of claim 1, further comprising representing on a heat map the aggregated efficiency benefit of each cell on the grid map for two or more of the plurality of times.

16. The method of claim 1, wherein the desired time period comprises a season.

17. The method of claim 1, wherein the desired time period comprises a given week of the year.

18. A distributed computing system comprising:
a distributed database configured to store flight simulation data and geographical restrictions data; and
one or more processors configured to:
compute a launch delay for a plurality of times within a desired time period for each cell in a grid map, the grid map comprising a target zone and an existing site,
compute a flight time to target for a delay time, the delay time comprising a time of the plurality of times plus the time's respective launch delay, the flight time to target indicating an amount of time for an aerial vehicle to travel from a respective cell in the grid map to a target zone on the grid map,
compute a launch time to target based on the launch delay and the flight time to target,
receive geographical restrictions data, and
determine an efficiency benefit over the existing site based on the geographical restrictions data and a comparison of the launch time to target of each cell with the launch time to target of the existing site for each of the plurality of times.
